(19) United States
(12) Patent Application Publication
(10) Pub. No.: US 2007/0072329 A1
(43) Pub. Date: Mar. 29, 2007

(54) METHOD AND APPARATUS FOR MANUFACTURING A DISPLAY APPARATUS

(76) Inventors: Takumi OGURI, Warabi-shi (JP); Hajime Tanaka, Hiratsuka-shi (JP); Yasunori Gamo, Fukaya-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/562,435

(22) Filed: Nov. 22, 2006

Related U.S. Application Data
(63) Continuation of application No. PCT/JP05/11472, filed on Jun. 22, 2005.

(30) Foreign Application Priority Data
Jun. 25, 2004 (JP) 2004-187936

(51) Int. Cl. H01L 21/00

(52) U.S. Cl. 438/50; 438/51; 438/55

(57) ABSTRACT

A light-shielding layer is formed and patterned on a front substrate that is opposed to a back substrate and on which a number of electron-emitting elements are arranged. A phosphor layer is formed and patterned on the part on which the light-shielding layer is not provided. A metal back layer is formed on the phosphor layer. A mechanical dividing means is positioned relative to the front substrate. The mechanical dividing means is moved relative to the front substrate, along dividing lines that extend along the shot sides or long sides of the front substrate, mechanically dividing the metal back layer.

### CROSS REFERENCE TO RELATED APPLICATIONS

This is a Continuation Application of PCT Application No. PCT/JP2005/011472, filed Jun. 22, 2005, which was published under PCT Article 21(2) in Japanese.

This application is based upon and claims the benefit of priority from prior Japanese Patent Application No. 2004-187936, filed Jun. 25, 2004, the entire contents of which are incorporated herein by reference.

### BACKGROUND OF THE INVENTION

1. Field of the Invention

The present invention relates to a method and apparatus for manufacturing a display apparatus. More particularly, the invention relates to a method and apparatus for manufacturing a planer-type display apparatus that has electron-emitting elements.

2. Description of the Related Art

Recently, planer-type display apparatuses have been developed as next-generation display apparatuses having a number of electron-emitting elements that are opposed to the fluorescent screen. Electron-emitting elements are available in various types. Basically, any type of an electron-emitting element utilizes electric-field emission. Any display apparatus having such electron-emitting elements is generally called field-emission display (hereinafter referred to as FED). Of FEDs, one having surface-conduction type electron-emitting elements is called surface-conduction type, electron-emission display (hereinafter referred to as FED). In the present specification, however, “FED” is used to mean any field-emission display, including Seeds.

To impart practical display characteristics to the FED, it is necessary to use a fluorescent screen which comprises a phosphor layer of the same type as used in ordinary cathode-ray tubes and a thin aluminum film call “metal back” and provided on the phosphor layer. When collided with electrons emitted from an electron source, the phosphor layer emits light. The metal back reflects that part of the light which travels toward the electron source. This part of light is guided to the front substrate, enhancing the luminance of the screen.

In the FED, however, the gap between the front substrate and the back substrate cannot be so large because of the resolution and the properties of the members supporting the substrates. The gap needs to be about 1 to 2 mm. Consequently, an intense electric field is generated in the narrow gap between the front substrate and the back substrate. If the FED goes on displaying images for a long time, discharge is likely to develop between the substrates (i.e., planer discharge between the metal backs; vacuum arc discharge). Once discharge has developed, a discharge current as large as several amperes to hundreds of amperes flows instantaneously. The electron-emitting elements of the cathode unit and the fluorescent screen of the anode unit may be broken or damaged. The discharge that may result in such a trouble should be avoided cannot be allowed to occur in the product. To put the FED to practical use, some measures must be taken to make it free of damages due to discharge.

Jpn. Pat. Appln. KOKAI Publication No. 10-326583 discloses the technique of dividing a metal back layer (Al layer) used as anode electrode into segments and connecting the segments to a common electrode provided outside the phosphor screen, by using resistor members.

However, the intervals between the dividing lines are extremely narrow in the arrangement of pixels on the FED phosphor screen. It is therefore difficult to cut slits having a width equal to the intervals, thus dividing the metal back layer into segments without dislocating the pixels provided on the FED fluorescent screen.

The metal back layer may be divided by laser cutting technology or laser abrasion technology. In either case, however, the heat generated as the laser beam is applied may damage the underlying layer or the substrate, and the edge of each metal-back segment may warp.

### BRIEF SUMMARY OF THE INVENTION

The present invention has been made to solve the problems described above. An object of the invention is to provide a method and apparatus for manufacturing a display apparatus, which can reliably and safely divide a metal back layer into segments, without imposing thermal influence, so that the electron-emitting elements or the fluorescent screen of the display apparatus may be prevented from degrading due to discharge and the display apparatus may display high-luminance, high-quality images.

A method of manufacturing a display apparatus, characterized by comprising: forming a patterned light-shielding layer on a front substrate opposed to a back substrate on which a number of electron-emitting elements are arranged, forming a patterned phosphor layer on a part on which the light-shielding layer is not provided; forming a metal back layers on the phosphor layer; aligning a mechanical diving means and the front substrate with each other; and moving the mechanical dividing means along dividing lines extending along a short side or a long side of the front substrate, relative to the front substrate, thereby mechanically dividing the metal back layer into segments.

An apparatus for manufacturing a display apparatus, characterized by comprising; a holding table configured to hold a rectangular substrate to be processed, which has a patterned phosphor layer and a metal back layer formed on the phosphor layer; mechanical dividing means for mechanically dividing the metal back layer of the substrate held on the holding table; means for detecting a position of at least one of the substrate held on the holding table and the mechanical dividing means, and for aligning the substrate and the mechanical dividing means relative to each other; and means for moving the mechanical dividing means relative to the substrate, along dividing lines extending along short sides of the substrate, while keeping the mechanical dividing means in contact with the metal back layer.

Various types of cutters can be used as mechanical dividing means. The dividing means may be, for example, a cutter comprising a support rod and a plurality of cutter blades which are secured to the support rod at a predetermined pitch and which do not rotate. Nonetheless, it is most desired that the mechanical dividing means be a rotary cutter that can be rotated. The roller cutter may be a driven type that can freely rotate or a driving type that rotates the cutter blades in the same direction that the blades move. Nevertheless, it is desired that the roller cutter be a reverse-drive type that rotates the cutter blades in the direction reverse to the direction the blades move. This is because the cutter blades bite deep into the Al metal back layer, sharply cutting the Al metal back layer. The reverse-drive type may have saw-toothed blades, not disk-shaped blades that have an edge continuous all along the circumference. Even in this case, the roller cutter can divide the metal back layer cleanly and continuously, into segments.

Preferably, the roller cutter comprises a plurality of split rollers arranged in a longitudinal direction, each supported by one follower means. The follower means may be shock-absorbing mechanisms, such as air cushions or air cylinders. Such follower means enable the split rollers of the roller cutter to flexibly move in accordance with the depressions and projections of the substrate being processed (i.e., metal back layer). The roller cutters can therefore reliably divide the layer into segments, cleanly over the entire thickness of the layer. Power-driven air cylinders may be used as follower means. In this case, the pressure applied to the cutter blades can be adjusted with high precision. The cutter blades will not bite into the light-shielding layer or the substrate, effectively avoiding damages to the light-shielding layer and the substrate.

Moreover, the chips made while the mechanical dividing means is dividing the metal back layer can be removed by chip-removing suction means. The chip-removing suction means may be a vacuum cleaner provided at an appropriate position near the roller cutter. Alternatively, suction grooves may be cut in the blades of the roller cutter.

The dividing lines may be set to correspond to vertical dividing lines along which the phosphor layer is to be divided into RGB pixels. Alternatively, they may be set to correspond to vertical dividing lines spaced at intervals along which the phosphor layer is be divided into multi-RGB-pixel units (two-pixel or three-pixel units).

The holding table can function not only as relative positioning means, but also as relative transporting means. It is used mainly as relative positioning means for positioning the substrate in the XY plane, relative to the mechanical dividing means. Preferably, the holding table is an XYZθ table that can be driven by a θ-rotation mechanism, rotating around the Z axis. To divide the metal back layer into segments, the mechanical dividing means or the XYZθ table may be moved in the Y direction (along the short sides of the substrate being processed), or both the only the XYZθ table may e or both the dividing means and the XYZθ table may be moved in the Y direction.

### BRIEF DESCRIPTION OF THE SEVERAL VIEWS OF THE DRAWING

FIG. 1 is a block plan view showing the configuration of an apparatus used in a method of manufacturing a display apparatus, according to the present invention;

FIG. 2 is a perspective view showing a roller cutter and a substrate to be processed;

FIG. 3 is a side view showing the roller cutter and the substrate to be processed;

FIG. 4A is a magnified view of the edge of a roller cutter;

FIG. 4B is a magnified view of the edge of another type of a roller cutter;

FIG. 4C is a magnified view of the edge of still another type of a roller cutter;

FIG. 4D is a magnified view showing the edge of a roller cutter and a suction mechanism;

FIG. 5A is a sectional view depicting a substrate that is being processed in a step of the manufacturing method according to this invention;

FIG. 5B is a sectional view depicting a substrate that is being processed in another step of the manufacturing method according to this invention;

FIG. 5C is a sectional view depicting a substrate that is being processed in still another step of the manufacturing method according to this invention;

FIG. 5D is a sectional view depicting a substrate that is being processed in a further step of the manufacturing method according to this invention;

FIG. 5E is a sectional view depicting a substrate that is being processed in another step of the manufacturing method according to this invention;

FIG. 5F is a sectional view depicting a substrate that is being processed in still another step of the manufacturing method according to this invention;

FIG. 6 is a partly cutout, plan view of a display apparatus (FED) according to this invention, showing the fluorescent screen and metal back of the front substrate;

FIG. 7 is a magnified plan view of a part of the display apparatus (FED) according to this invention;

FIG. 8 is a perspective view showing the configuration of the display apparatus (FED) according to this invention; and

FIG. 9 is a sectional view of the display apparatus, taken along line A-A shown in FIG. 8.

### DETAILED DESCRIPTION OF THE INVENTION

The best mode for carrying out the invention will be described, with reference to the accompanying drawings.

### First Embodiment

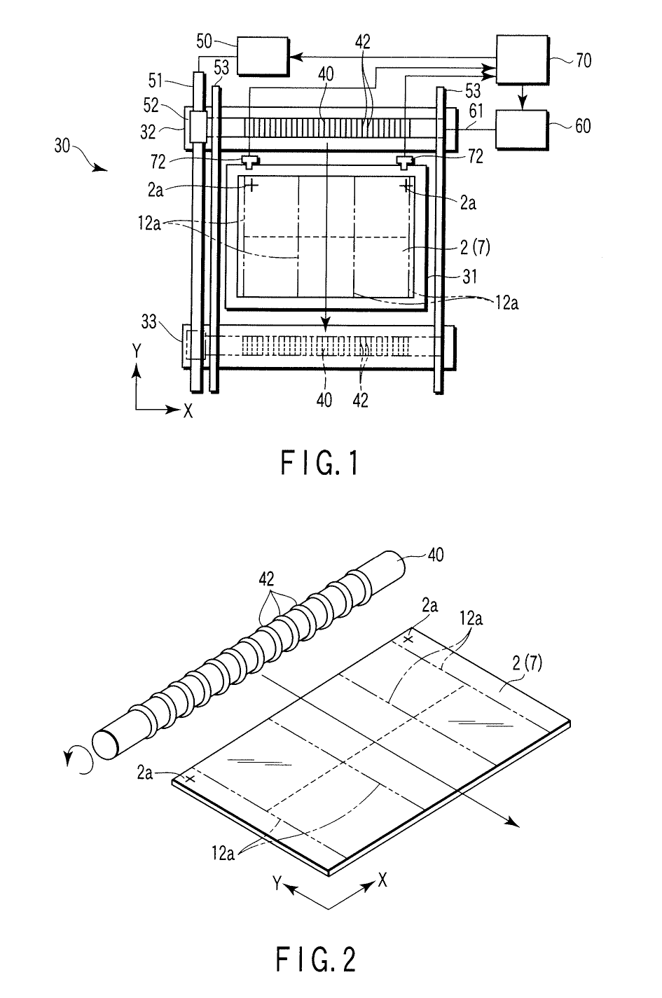

A first embodiment of the present invention will be described, with reference to FIG. 1 and FIG. 2. FIG. 1 shows a thin-film cutting apparatus 30, which is an apparatus for manufacturing a display apparatus, according to the present invention. As shown in FIG. 1, the apparatus 30 comprises an XYZθ table 31, a waiting unit 32, a washing-drying unit 33, a roller cutter 40, a roller-driving unit 50, a roller-rotating unit 60, a controller 70, and position sensors 72.

The XYZθ table 31 plays a role of a table for holding a front substrate 2 that is to be processed. The table 31 has a rectangular upper surface that is slightly larger than the substrate 2. The table 31 has a plurality of vacuum suction holes. The holes open at the upper surface and are used to hold, by suction, the substrate 2 on the upper surface of the table 31. The substrate 2 is held on the XYZθ table 31, with its long side extending in X direction and its short side extending in Y direction. The position sensors 72 are provided above the XYZθ table 31. They can optically detect alignment marks 2a that are provided on the corners of the substrate 2. Note that the sensors 72 are fixed in place, not to be displaced with respect to the system that drives the roller cutter 40.

The three direct-drive mechanisms (not shown) can drive the XYZθ table 31 in X direction, Y direction and Z direction, respectively. Further, a θ-rotation drive mechanism (not shown, either) can rotate the XYZθ table 31 around the X axis. The controller 70 controls these table-driving mechanisms in accordance with the alignment-mark detection signals supplied from the position sensors 72.

The waiting unit 32 is provided, extending along one long side of the waiting unit 32 is located at the home position of the roller cutter 40. As long as the roller cutter 40 remains not used (while being inspected for maintenance), it is held at the waiting unit 32.

The washing-drying unit 33 is arranged, extending along the other long side of the XYZθ table 31. The washing-drying unit 33 is located at the end position of the roller cutter 40. The unit 33 has a washing nozzle (not shown) and a drying nozzle (not shown, either). The washing nozzle and the drying nozzle applies washing liquid and dry air, respectively, to the roller cutter 40 immediately after the cutter 40 is used.

A pair of linear guides 53 and a ball screw 51 are provided, each extending from the waiting unit 32 to the washing-drying unit 33. A ball nut 52 is mounted in mesh on the ball screw 51. To the ball nut 52, the roller cutter 40 is coupled at one end. The ends of the roller cutter 40 are mounted and can slide on the left and right liner guides 53, respectively. The roller-driving unit 50 has a drive shaft, which is coupled to the ball screw 51. The controller 70 controls the timing of staring and stopping the rotation of the ball screw 51 and the rotation speed and direction of the ball screw 51.

The roller-rotating unit 60 has a drive shaft 61, which is connected to the roller cutter 40. The controller 70 controls the timing of staring and stopping the rotation of the roller cutter 40 and the rotation speed and direction of the roller cutter 40.

As shown in FIG. 2, the roller cutter 40 has a number of cutter blades 42. Each cutter blade 42 has saw teeth and is formed all around the circumference of the roller. The cutter blades 42 are secured at a predetermined pitch, spaced apart from one another. The cutter blades 42 are soft grinding stones so that they may not damage glass plates. Instead, they may be made of hard metal or hard grinding stone containing diamond particles. The cutter blades 42 have a width of preferably about 2 to 20 μm, depending on the type of blades. This is because slits broader than the vertical dividing lines cannot be made to divide the metal back into segments. There is the tendency that width of the dividing lines is equal to or a little greater than the edge width of the cutter blades 42. It is desired that the main body of the roller cutter 40 have a diameter ranging form 10 mm to 60 mm. If the diameter is less than 10 mm, the roller cutter 40 will be less rigid than desired and may bend. If the diameter exceeds 60 mm, the roller cutter 40 will be too heavy. Preferably, the main body of the roller cutter 40 is made of hard resin or hard metal so that it may hardly be deform and make particles.

The operation of the thin-film cutting apparatus 30 described above will be explained briefly.

A transportation robot (not shown) places on the XYZθ table 31 a substrate 2 that is to be processed. The substrate 2 is automatically aligned with the XYZθ table 31, though somewhat coarsely. This is because the table 31 has self-alignment structure on its upper surface. The substrate 2 to be processed is the front substrate of an FED. One surface of the substrate 2 is covered with a metal back layer made of Al. The substrate 2 is placed on the XYZθ table 31, with the Al metal back layer turned upwards. A vacuum chuck holds the substrate 2 by suction.

The position sensors 72 optically detect the alignment marks 2a provided on the corners of the substrate 2 and generates detection signals. In accordance with the detection signals, the controller 70 minutely adjusts the position of the XYZθ table 31 in the XY plane and the position (height) of the XYZθ table 31 in the Z direction. The substrate 2 to be processed is thereby aligned with the roller cutter 40 at high precision. As a result, the dividing lines 12a on the substrate are aligned with the cutter blades 42, in one-to-one relation.

When the substrate and the roller cutter are aligned with each other, the controller 70 sends signals to the roller-driving unit 50 and the roller-rotating unit 60. The roller cutter 40 is thereby made to start moving in the Y direction (along the short side of the substrate) and to rotate in reverse direction. The roller cutter 40 moves from the waiting unit 32 toward the substrate. Guided by the left and right linear guides 53, the roller cutter 40 contacts and bites into the metal back layer 7 of the substrate 2 held on the table 31. The roller cutter 40 is further moved in the Y direction (along the short side of the substrate). As the roller cutter 40 so moves, it divides the Al metal back layer 7 into segments, along the dividing lines 12a.

The roller cutter 40 runs over the substrate 2 and stops upon arriving at the washing-drying unit 33. At the washing-drying unit 33, the washing liquid (hot water or solvent) is applied, in the form of a jet stream, to the roller cutter 40, removing Al chips from the cutter blades 42. The Al chips thus removed enter a cup-shaped vessel (not shown), along with the washing liquid, and is discharged from the washing-drying unit 33 through a drain pipe (not shown). Dry air is applied to the roller cutter 40, drying the cutter 40. The roller cutter 40 thus dried is moved from the washing-drying unit 33, back to the waiting unit 32. While the roller cutter 40 is being washed and dried, the substrate 2 being processed is lifted from the table 31 by the transportation robot and transported from the apparatus 30 to the site where it undergoes the next manufacturing step.

While the apparatus 30 is processing each substrate 2 as described above, the roller cutter 40 is washed and dried. The cutter blades 42 are therefore kept clean. The clean cutter blades 42 are used, cutting the metal back layer 7.

### Second Embodiment

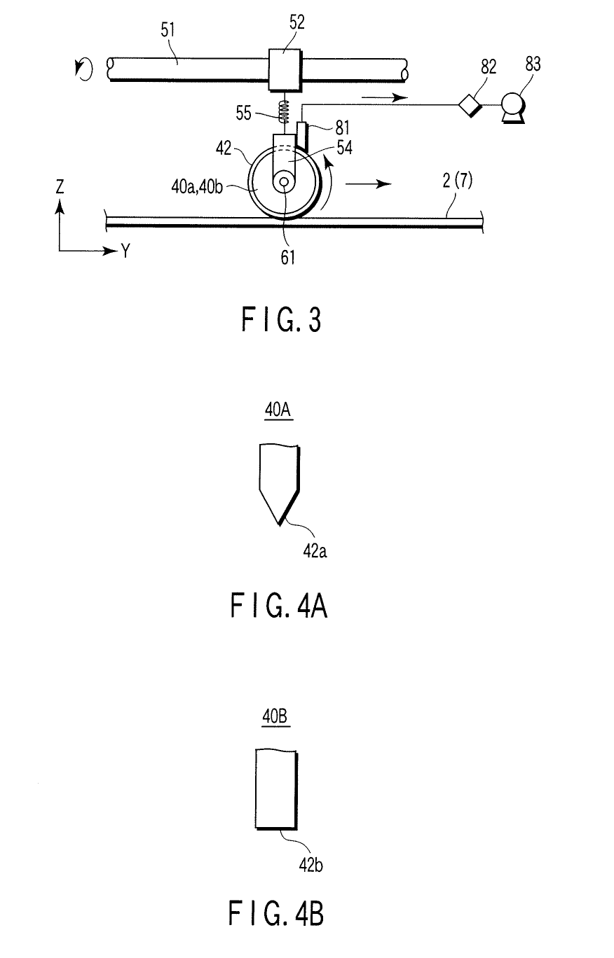

A second embodiment of the present invention will be described with reference to FIG. 3.

The roller cutter of the second embodiment comprises two roller cutters 40a and 40b that are divided and has the same length. The rollers 40a and 40b are supported by holders 54 and can rotate around shafts 61. Each holder 54 is coupled to a ball nut 52 by a compression spring 55 and a connecting rod (not shown). The compression spring 55 is a follower means for helping the cutter blade 42 of the roller cutter to move flexibly in the Z direction. Hence, the roller cutters 40a and 40b divide an Al metal back layer 7, slightly moving up and down as they move in contact with minute depressions and projections of the Al metal back layer 7. Since the compression springs 55 pushes the cutter blades 42 onto the Al metal back layer, applying a predetermined pressure (low pressure) to the meta back layer, the blade 42 do not bite into the substrate located beneath the metal back layer. This embodiment has two roller cutters. Nonetheless, three, four, five, six, seven or eight roller cutters may be used in the present invention. However, it is not desirable to use nine or more roller cutters. If so many roller cutters are used, the mechanism supporting them will be complex and the cutter unit will become too heavy.

The roller cutters of this embodiment have a vacuum cleaner 81 each. The vacuum cleaner 81 communicates with a vacuum pump 83 through a filter 82 and opens in the vicinity of the cutter blade 42 of the cutter 40. The cleaner 81 can therefore remove Al chips by suction, immediately the Al chips are made while the roller cutter is operating. Hence, the substrate can be effectively prevented from becoming dirty with particles.

This embodiment uses compression springs as follower means for moving the roller cutters flexibly. Nevertheless, shock-absorbing mechanisms, such as air cushions or air cylinders, may be used instead. Such follower means enable the cutter blades to move in accordance with the depressions and projections of the substrate being processed (i.e., metal back layer). The roller cutters can therefore reliably divide the layer into segments, cleanly over the entire thickness of the layer. Power-driven air cylinders are used as follower means, the pressure applied to the cutter blades can be adjusted with high precision. In this case, the cutter blades will not bite into the light-shielding layer or the substrate, effectively avoiding damages to the light-shielding layer and the substrate.

### Third Embodiment

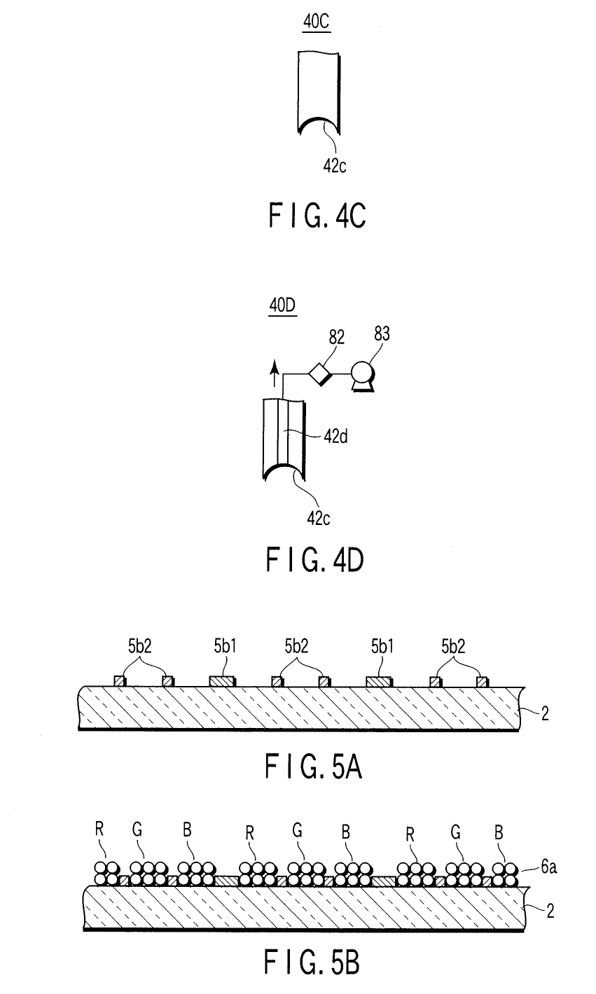

A third embodiment of the present invention will be described, with reference to FIG. 4A to FIG. 4D.

The embodiment can use such various types of roller cutters 40a, 40b and 40c as shown in FIG. 4A to FIG. 4D. The roller cutter 40a shown in FIG. 4A has a cutter blade 42a that has a projecting edge. The cutter blade 42a can cut slits having a minimum width of a few microns, in an Al metal back layer. The roller cutter 40b shown in FIG. 4B has a cutter blade 42b that has a flat edge. The cutter blade 42b can cut slits having a prescribed width, in an Al metal back layer.

The roller cutter 40c shown in FIG. 4C has a cutter blade 42c that has a depressed edge. The cutter blade 42c makes it easy to transport Al chips made during the cutting process, to a vacuum cleaner 81. The roller cutter 40d shown in FIG. 4D has a cutter blade 42c that has a depressed edge, like the blade described above. The cutter blade 42c has a suction groove 42 that communicates with a vacuum pump 83 through a filter 82. This cutter blade 42c serves to remove Al chips more efficiently.

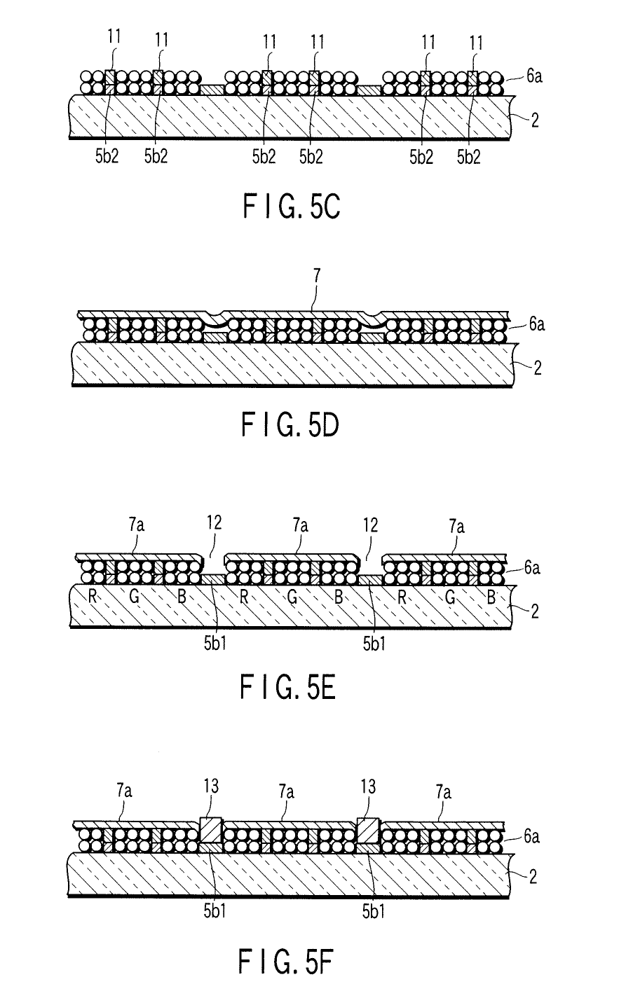

A method of manufacturing an FED, i.e., a display apparatus, according to the present invention, will be explained with reference to FIG. 5A to FIG. 5F.

A glass substrate 2 that will be the front substrate of the FED is washed with a prescribed chemical liquid. The substrate 2 therefore acquires desirable clean surfaces. Solution for forming a light-shielding layer, which contained light-absorbing agent such as black pigment, was applied to the inner side of the front substrate 2 thus washed. The resulting coating was heated and dried. Thereafter, the coating was exposed to light through a screen mask that had openings corresponding to a matrix pattern. The coating was then developed, providing matrix-patterned light-shielding layers 5b1 and 5b2.

Next, phosphor layers 6a, some being red (R), some other being green (G), and the others being blue (B), were formed by ordinary method on the regions in which no light-shielding layers 5b1 or 5b2 were arranged in a matrix pattern. As a result, there was obtained a fluorescent screen that had rectangular or strip-shaped phosphor layers 6a of tricolor pattern, which were regularly arranged in rows and columns as shown in FIG. 5B. The screen may have squire pixels arranged at pitch of, for example, 600 μm. If this is the case, the vertical dividing lines between the phosphor layers 6a need to have a width ranging, for example, 20 to 50 μm in the X direction. The horizontal dividing lines (stripes) between the phosphor layers 6a have a width of, for example, 50 to 250 μm in the Y direction. Matrix pattern shield layers 5 were provided along the vertical and horizontal dividing lines. The layers 5 can prevent light from leaking toward the front substrate 2.

Resistor layers 11 were laid on the pattern shield layers 5b2 that were spaced apart for a short distance. The resistor layers 11 were positioned almost flush with the phosphor layers 6a as shown in FIG. 5C.

Next, an Al metal back layer 7 was formed on the entire surface of the substrate 2 being processed, as is illustrated in FIG. 5D. That is, an aluminum (Al) film was formed by vacuum vapor deposition, on a thin film of organic resin such as nitroglycerine, which had been formed by, for example, spin coating. The layer 7 may be baked to remove the organic substance.

Then, the Al metal back layer 7 was mechanically cut along the dividing lines, with the roller cutter 40 described above. The Al metal back layer 7 was thereby cut into segments for RGR pixels. Al metal-back-layer segments 7a were thereby formed as shown in FIG. 5E. In this embodiment, the roller cutter 40 cut the layer 7 at a speed ranging from 10 to 200 mm/sec.

Next, resistor layers 13 were laid on the pattern shield layers 5b1 that were spaced apart for a long distance. The resistor layers 13 were positioned almost flush with the phosphor layers 6a as shown in FIG. 5F.

Subsequently, the phosphor screen 6 thus formed was arranged outside a vacuum envelope, along with electron-emitting elements. The vacuum envelope had been formed by sealing the front substrate 2 having the phosphor screen 6 and the back substrate 1 having the electron-emitting elements, by using flit glass or the like. In the vacuum envelope, prescribed getter material was vapor-deposited from above the pattern. A vapor-deposited getter film was thereby formed on the region of the Al metal back layer 7.

In the FED thus fabricated, the gap between the front substrate 2 and the back substrate 1 is extremely narrow. Therefore, discharge (dielectric breakdown) is likely to occur between these substrates. Even if discharge occurs, the peak discharge current is suppressed, avoiding an instantaneous concentration of energy. This is because the metal back layer 7 divided into pixel segments remains intact on the pattern-formed phosphor layer 6a. Since the maximum value of discharge energy is reduced, the electron-emitting elements and the phosphor screen are prevented from being broken or damaged.

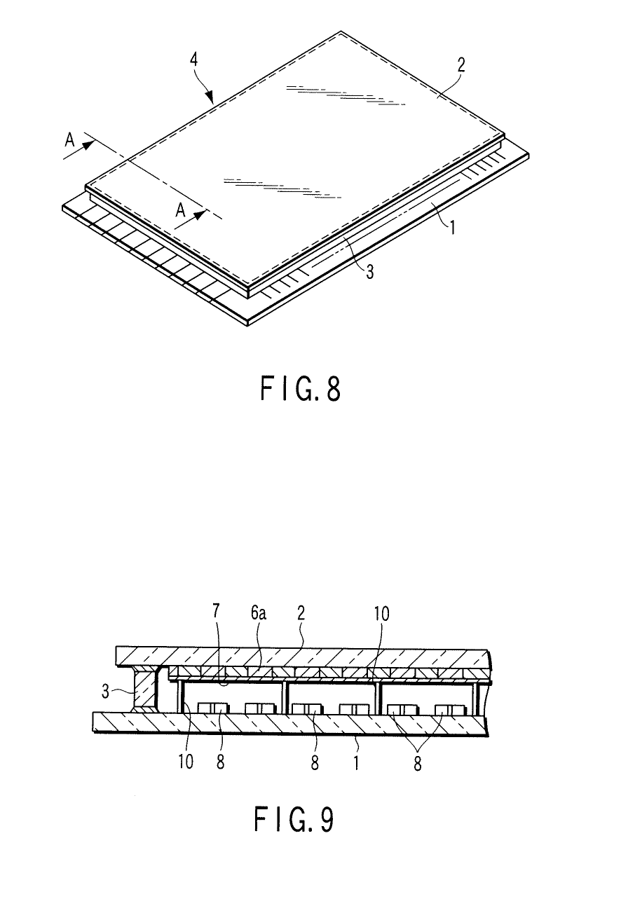

FIG. 8 and FIG. 9 shows the EFD structure common to this embodiment. The FED has a front substrate 2 and a back substrate 1 that are rectangular glass plates. The substrates 1 and 2 are opposed to each other, spaced apart by 1 to 2 mm. The front substrate 2 and the back substrate 1 are bonded at edges, with a sidewall 3, or a rectangular frame, interposed between them. The substrates 1 and 2 and the sidewall 3 constitute a flat, rectangular vacuum envelope 4 maintained at high vacuum inside.

A phosphor screen 6 is provided on the inner side of the front substrate 2. The phosphor screen 6 is constituted by phosphor layers 6a and a matrix-patterned light shield layer 22b. The phosphor layers 6a emit red (R) light, green (G) light and blue (B) light. A metal back layer 7, which functions as anode electrode, is formed on the phosphor screen 6. The layer 7 functions as a light-reflecting film that reflects the light emitted from the phosphor layers 6a. While the display is operating, a predetermined anode voltage is applied to the metal back layer 7 from a circuit (not shown).

A number of electron-emitting elements 8 are provided on the inner side of the back substrate 1. These elements 8 can emit electrons that excite the phosphor layer 6a. The electron-emitting elements 8 are arranged in rows and columns, in one-to-one correspondence to pixels. The electron-emitting elements 8 are driven by liens (not shown) that are arranged in a matrix pattern. A number of spacers, each shaped like a plate or a pillar, are provided between the back substrate 1 and the front substrate 2 so that these substrates 1 and 2 may withstand the atmospheric pressure applied to them.

An anode voltage is applied to the phosphor screen 6 through the metal back layer 7. The anode voltage accelerates the electron beams emitted from the electron-emitting elements 8. The electrons accelerated collide with the phosphor screen 6. As a result, the phosphor layers 6a irradiated with the electron beams emit light, whereby an image is displayed.

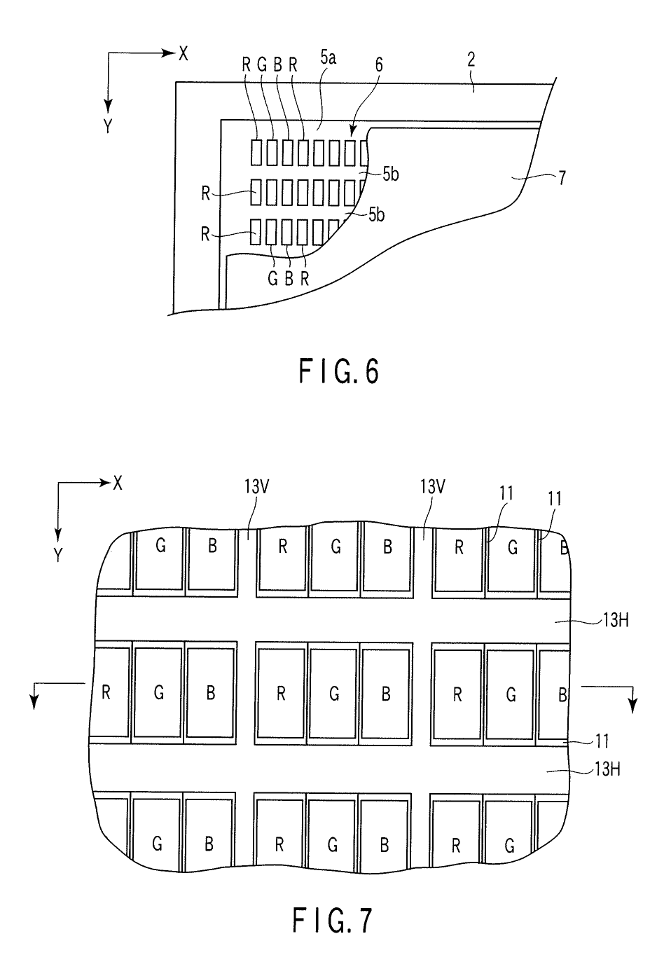

FIG. 6 depicts the structure of the front substrate 2, particularly the structure of the phosphor screen 6, which is common to the embodiments of the present invention. The phosphor screen 6 has a number of rectangular phosphor layers, which can emit red (R), green (G) and blue (B) light beams. Assume that the longitudinal direction of the front substrate 1 is X axis and that the direction intersecting with the X axis at right angles is Y axis. Then, the phosphor layers R, G and B are repeatedly arranged in the sequence mentioned, in the X-axis direction at predetermined intervals. In the Y-axis direction, phosphor layers of the same color are arranged at predetermined intervals. The predetermined intervals may change during the manufacture by an allowable value or by a design tolerance. Therefore, the phosphor layers 6a cannot be said to be arrange at regular intervals. For convenience, however, they are considered arranged at almost regular intervals.

The phosphor screen 6 has a light-shielding layer 5. As shown in FIG. 6, the light-shielding layer 5 has two light-shielding layers 5a and 5b. The layer 5a is shaped like a rectangular frame. The layer 5b is a matrix pattern. The light-shielding layer 5a extends along the edges of the front substrate 2. The light-shielding layer 5b lies inside the light-shielding layer 5a and extends between the phosphor layers R, G and B.

Resistor layers 13 are laid on the matrix-patterned light-shielding layer 5b and extend along vertical dividing lines 13V that extend in the Y direction. Resistor layers are laid on the matrix-patterned light-shielding layer 5b and extend along horizontal dividing lines 13H that extend in the X direction. Resistor layers 11 that extend in the Y direction isolate the phosphor segments R, G and B from one another. The vertical dividing lines 13V and the horizontal dividing lines 13H have been formed by ordinary photolithography, using material in which metal oxide particles having a predetermined resistivity are used as matrix material.

In the present invention, the metal back layer is divided into segments by mechanical means. This can prevent discharge from occurring in a planer display such as an FED and can suppress the peak discharge current even if discharge occurs in the display. Thus, the electron-emitting elements and the phosphor screen can be prevented from being broken, damaged or degraded. In particular, the mechanical dividing of the metal back layer results in no thermal damage to the other components around the layer in the present invention. The invention is therefore advantageous in that the electron-emitting elements or the phosphor screen (particularly, the phosphor layers) can be free of thermal degradation.

What is claimed is:

1. A method of manufacturing a display apparatus, comprising:
forming a patterned light-shielding layer on a front substrate opposed to a back substrate on which a number of electron-emitting elements are arranged,
forming a patterned phosphor layer on a part on which the light-shielding layer is not provided;
forming a metal back layers on the phosphor layer;
aligning a mechanical diving means and the front substrate with each other; and
moving the mechanical dividing means along dividing lines extending along a short side or a long side of the front substrate, relative to the front substrate, thereby mechanically dividing the metal back layer into segments.

2. The method according to claim 1, wherein a roller cutter having blades on an entire circumferential surface is used as the mechanical dividing means.

3. The method according to claim 2, wherein the roller cutter is rotated in a direction reverse to a moving direction, thereby cutting the metal back layer into segments.

4. The method according to claim 2, wherein the roller cutter comprises a plurality of split roller cutters arranged in a longitudinal direction, and each of the split roller cutters is supported by one follower means.

5. The method according to claim 2, wherein chips made while the mechanical dividing means is dividing the metal back layer into segments are removed by suction.

6. The method according to claim 1, wherein the dividing lines are set to correspond to vertical dividing lines along which the phosphor layer is to be divided into pixels.

7. An apparatus for manufacturing a display apparatus, comprising;
a holding table configured to hold a rectangular substrate to be processed, which has a patterned phosphor layer and a metal back layer formed on the phosphor layer;
mechanical dividing means for mechanically dividing the metal back layer of the substrate held on the holding table;
means for detecting a position of at least one of the substrate held on the holding table and the mechanical dividing means, and for aligning the substrate and the mechanical dividing means relative to each other; and
means for moving the mechanical dividing means relative to the substrate, along dividing lines extending along short sides of the substrate, while keeping the mechanical dividing means in contact with the metal back layer.

8. The apparatus according to claim 7, wherein the mechanical dividing means is a roller cutter which has blades on the circumferential surface and which can rotate.

9. The apparatus according to claim 8, further comprising a roller-rotating unit which rotates the roller cutter in a direction reverse to a direction in which the roller cutter moves.

10. The apparatus according to claim 8, wherein the roller cutter comprises a plurality of split roller cutters arranged in a longitudinal direction, and has a plurality of follower means, each supporting one split roller.
